(19) United States
(12) Patent Application Publication
(10) Pub. No.: US 2009/0021270 A1
(43) Pub. Date: Jan. 22, 2009

(54) CAPACITIVE DETECTION OF DUST ACCUMULATION IN A HEAT SINK

(75) Inventors: Justin Potok Bandholz, Cary, NC (US); Zachary Benson Durham, Asheboro, NC (US); Clifton Ehrich Kerr, Durham, NC (US); Joseph Eric Maxwell, Cary, NC (US); Kevin Michael Reinberg, Chapel Hill, NC (US); Kevin S. Vernon, Durham, NC (US); Philip Louis Weinstein, Apex, NC (US); Christopher Collier West, Raleigh, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 11/780,233

(22) Filed: Jul. 19, 2007

(51) Int. Cl. G01R 27/26

(52) U.S. Cl. 324/690

(57) ABSTRACT

A system and method for electronically detecting the accumulation of dust within a computer system using a capacitive dust sensor. The dust detection system may be implemented on a smaller computer, such as an individual PC, or in a more expansive system, such as a rack-based server system (“rack system”) having multiple servers and other hardware devices. In one embodiment, each server in a rack system includes a capacitive sensor responsive to the accumulation of dust. The capacitive sensor may include one or more capacitive plates integral with a heatsink. As dust collects on the capacitive plates, the capacitance increases. When a capacitance setpoint is reached, indicating the dust has reached a critical level, an alert is generated. The alerts may be received by a management console for the attention of a system administrator. Each alert may contain the identity of the server generating the alert, so that the system administrator knows which server(s) are to be removed for cleaning.

### BACKGROUND OF THE INVENTION

1. Field of the Invention

The present invention relates to the detection and removal of dust in electronic systems.

2. Description of the Related Art

Airflow is commonly used to remove heat generated by components within a computer. For example, an individual PC typically includes one or more on-board cooling fans disposed within the housing to cool the processors, power supply, memory, and other internal components. In more expansive computer systems, such as rack-based computer systems having multiple servers, one or more blower modules are supported on a chassis along with the servers to generate airflow through the servers and other components. Despite efforts to keep a computer center clean and filter dust out of the air, the airflow used to cool a computer carries some amount of dust, which accumulates over time on internal components of the computer. The electrostatic charge generated by some components tends to attract dust, increasing the amount and rate of dust deposited.

Unfortunately, dust accumulation can cause problems in a computer system. Excessive dust build-up can reduce performance, increase the rate at which components fail, and reduce overall system reliability. Dust can interfere with operation of moving parts, such as fan blades and mechanical connectors, and reduce the reliability of electrical components, such as by dirtying electrical contacts in electrical connectors. Dust can even give off an unpleasant odor in the presence of hot components.

Dust can be especially problematic for heatsinks. A heatsink typically protrudes beyond neighboring components, positioning the heatsink well into the airflow for cooling. Thus, dust may accumulate more heavily on a heatsink than on other components. Dust deposited on heatsink fins can reduce the thermal efficiency of the heatsink, which affects the temperature and cooling performance of the hardware device in contact with the heatsink. These effects are compounded in rack systems having many servers that each contains one or more processors and dust-accumulating heatsinks. Furthermore, the need to remove and inspect each server and other hardware devices for accumulated dust causes an increase in the time and associated expense involved with system maintenance.

It may not be readily apparent when enough dust has accumulated within a hardware device to require servicing the hardware device. Typically, hardware devices must be manually checked for dust build-up. Manually inspecting hardware for dust is inefficient, usually necessitating the removal of the hardware from the chassis. In many cases, the system must be off line, and a service person needs to physically disassemble the system.

An improved dust detection system and method are needed, particularly in view of the difficulty in ascertaining dust accumulation using conventional techniques. Improvements in the speed and ease of dust detection would be especially desirable in larger computer systems such as rack systems having numerous servers and other hardware. It would be particularly desirable to have a system and method that would automatically detect the accumulation of dust.

### SUMMARY OF THE INVENTION

The present invention provides systems and methods for detecting dust accumulation in air-cooled hardware devices, such as convection-cooled blade servers. One embodiment provides a system for detecting dust accumulation in an air-cooled hardware device. At least two capacitive plates are disposed within the hardware device and define an air channel between the capacitive plates. The air channel is open to the interior of the hardware device. A sensor is in communication with the capacitive plates for sensing a capacitance between the capacitive plates. A controller is in communication with the sensor for detecting if a capacitance-related setpoint is reached or exceeded. The controller is configured to generate an alert if the setpoint is reached or exceeded. The alert may include the identity of the hardware device, such as to inform a system administrator that the hardware device needs servicing.

Another embodiment provides a method of detecting dust accumulation in an air-cooled hardware device. Airflow is generated through the hardware device. Capacitive plates are disposed within the hardware device, and an air channel between the capacitive plates open to the interior of the hardware device. The capacitance between the capacitive plates is monitored to determining if a capacitance-related setpoint is reached or exceeded. If the setpoint is reached or exceeded, an alert may be generated along with the identity of the hardware device, such as to inform a system administrator that the hardware device needs servicing.

Other embodiments, aspects, and advantages of the invention will be apparent from the following description and the appended claims.

### BRIEF DESCRIPTION OF THE DRAWINGS

FIG. 1 is a front elevation view of a conventional rack system having a plurality of blade servers.

FIG. 2 is a side elevation view of one of the blade servers with an outer housing removed to reveal some of the internal components on which dust accumulates.

FIG. 3 is a schematic, perspective view of one of the heatsinks configured with a dust detection system

FIG. 4 is a schematic side view of the dust detection system and the heatsink with an accumulation of dust.

FIG. 4A is a graph illustrating the relationship between the sensed capacitance C and the thickness of a dust layer on the capacitive plates.

FIG. 5 is a graph illustrating how the cooling efficiency η of the heatsink decreases as dust accumulates.

FIG. 6 is a schematic side view of an alternative embodiment of a heatsink and dust detection system, wherein one of the heatsink fins functions as an integral capacitive plate.

FIG. 7 is a schematic side view of yet another embodiment of a heatsink and dust detection system, wherein a plurality of capacitive plates are integrated with the fins of the heatsink.

### DETAILED DESCRIPTION OF PREFERRED EMBODIMENTS

The present invention provides a system and method for electronically detecting the presence of dust within a computer system using a capacitive sensor responsive to the accumulation of dust. The dust detection system may be implemented in a smaller computer, such as an individual PC, or in a more expansive system, such as a rack-based server system (“rack system”) having multiple blade servers and other hardware devices. In one embodiment, each blade server in a rack system detects the internal accumulation of dust within the blade server and generates an alert when the accumulation of dust has reached a certain level. The alerts may be received by a management console for the attention of a system administrator. Each alert may contain the identity of the blade server generating the alert, so that the system administrator knows which blade server(s) need to be cleaned. Identifying blade servers or other components that have an accumulation of dust results in tremendous savings in time, labor, and associated operating expense as compared with manually removing and individually inspecting each blade server for dust.

The dust detection system may include a plurality of capacitive plates positioned near a particular component, such as a heatsink, for at least inferentially detecting dust accumulation on that component. The capacitive plates are spaced apart for receiving some of the airflow between the plates. A sensor in electronic communication with the capacitive plates may generate a signal in response to sensing a change in the capacitance between the plates caused by the accumulation of dust between the plates. Furthermore, the capacitance between the plates may be monitored as an indication of accumulating dust. A setpoint may be determined in relation to the sensed capacitance. The setpoint may be, for example, the value of the “critical capacitance” corresponding to a predetermined maximum level of dust. Alternatively, the setpoint may be the differential between the initial (dust-free) capacitance and the critical capacitance. The dust detection system may sense the changing capacitance as dust accumulates and generate an alert when the setpoint is reached or surpassed.

A hardware device may include a component, such as a heatsink, having one or more integral capacitive plates. For example, the cooling fins of a heatsink may include at least one fin that functions as a capacitive plate for detecting dust between the fins. The changing capacitance between the fins may be sensed as an indication of the accumulation of dust. Integrating the capacitive plates with a component may more reliably and accurately detect dust within the vicinity of the heatsink. Integral capacitive plates may also minimize the combined form factor of the heatsink and dust detection system, allowing the integrated heatsink and dust detection system to be installed in a location normally allocated to a conventional heatsink.

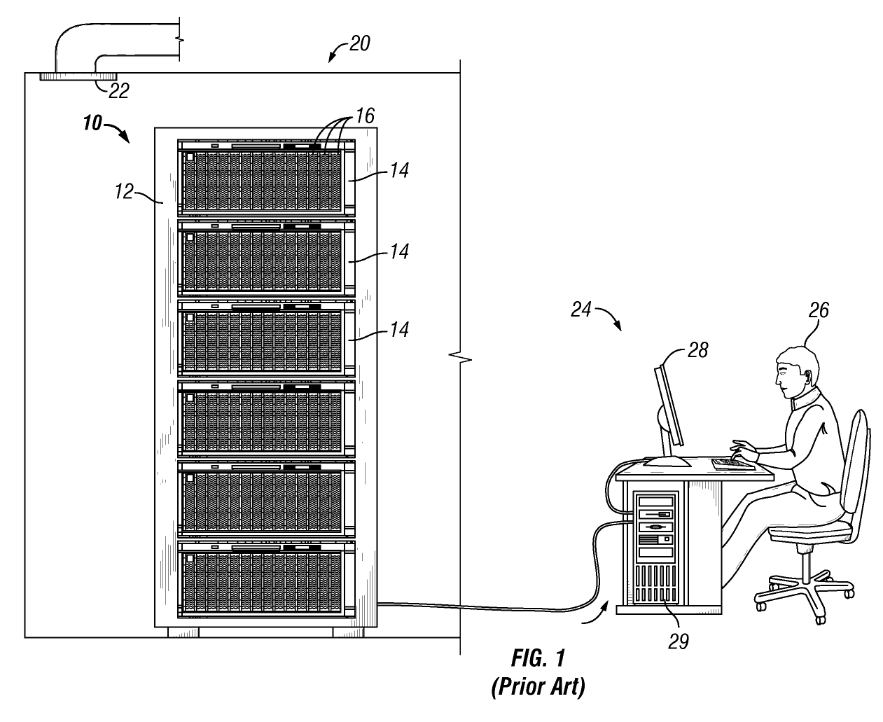

FIG. 1 is a front elevation view of a conventional, rack-based computer system (“rack system”) 10 in a data center 20. The rack system 10 is an example of a computer system having a plurality of blade servers and other air-cooled hardware devices in which dust will accumulate over time. The rack system 10 includes a rack 12 supporting six server chassis 14. Each server chassis 14 supports fourteen networked blade servers 16 per chassis, along with supporting hardware, such as power supplies, switches, and a management module. Thus, the rack 12 holds up to eighty-four heat-generating blade servers and support modules, all of which are air-cooled. Periodic maintenance on such a system may be costly and time consuming, particularly due to the large number of hardware devices involved.

Each server chassis 14 supports one or more blower module known in the art for circulating air through the server chassis 14 to cool the blade servers 16 and support modules within the server chassis 14. Heated air expelled from the rack system 10 is then taken up by an air intake 22 and circulated through a computer-room air-condition system (CRAC) that cools the air and returns it to the data center 20. As air blows through the blade servers 16 and other hardware devices, dust collects over time in each of the hardware devices in the rack system 10. The invention provides systems and methods for detecting the accumulation of dust in a blade server 16 or other hardware device without removal.

A workstation 24 is optionally networked with the blade servers 16 for helping a system administrator 26 monitor and control the blade servers 16 globally. The workstation 24 includes a management console 28, which has a customizable graphical administrative interface, and a management server 29, which can remotely control and support thousands of remote computer subsystems including the blade servers 16. Local software (e.g. a system “agent”) may be installed on each blade server 16, allowing the management server 29 to selectively interface with the various blade servers 16 to monitor and control the blade servers 16. For example, an agent installed on a particular blade server 16 may send a signal over the network to warn the system administrator 26 that intervention is required for that blade server.

The workstation 24 may include additional functionality pertaining to the detection of dust according to the invention. For example, each blade server 16 may detect the accumulation of dust on its components or within its housing and generate an alert signal when the amount of accumulated dust reaches a critical level that requires servicing the blade server 16. The alert signal may be received at the workstation 24 and reported by the management console 28. The system administrator 26 may monitor the management console 28 to know which specific hardware devices need servicing for dust removal at any particular time. This approach to monitoring the accumulation of dust within the individual hardware devices of the rack system 10 is more efficient than periodically removing and visually inspecting all the components to determine which hardware devices need cleaning.

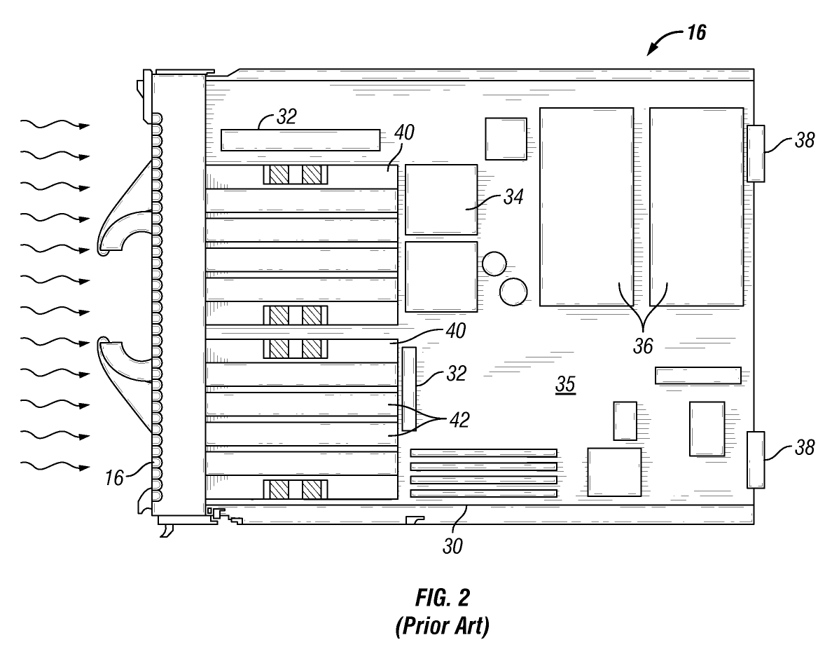

FIG. 2 is a side elevation view of one of the blade servers 16 with an outer housing removed to reveal some of the internal components on which dust accumulates. The internal components of the exemplary blade server 16 include four memory modules (DIMMs) 30, voltage regulators 32, control chips 34, two small form factor (SFF) hard drives 36, redundant power and signal connectors 38, and a pair of processor heatsinks 40 for cooling microprocessors (“CPUs”) disposed below the heatsinks 40. The components are generally mounted on a motherboard 35. The heatsinks 40 are typically formed of materials having high thermal conductivity, such as aluminum, to conduct heat away from the CPUs. Air blows over the heatsinks 40 to cool the heatsinks 40 via forced convection. A plurality of optional fins 42 are included with the heatsinks 40 to increase the surface area exposed to the airflow. The fins 42 project well into the cooling airflow that passes through the blade server 16. Consequently, the heatsinks 40 are especially prone to accumulating dust. The accumulation of dust reduces airflow between the fins and thus reduces the cooling efficiency of the heatsinks 40. This reduced cooling efficiency can impact the overall efficiency of the rack system 10, such as by requiring an increased airflow rate in order to sufficiently cool the blade servers 16.

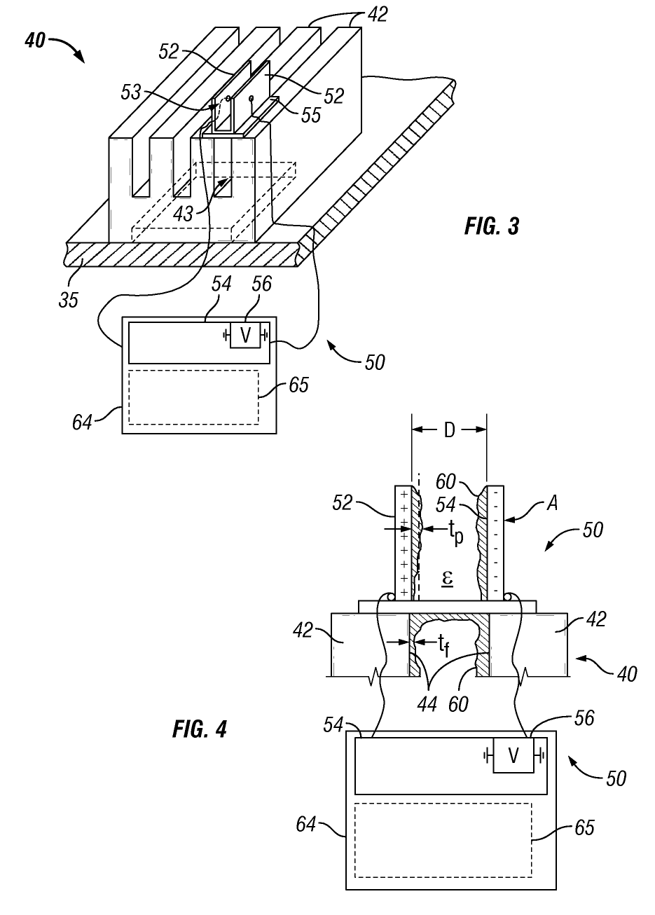

FIG. 3 is a schematic, perspective view of one of the heatsinks 40 configured with a dust detection system generally indicated at 50. The dust detection system 50 includes a pair of capacitive plates 52 mounted on an electrically insulating substrate 55 to the heatsink 40, and a controller 64 having a capacitance sensing device (“sensor”) 54 in electronic communication with both of the capacitive plates 52. The controller 64 may include, for example, a CPU or a baseboard management controller (BMC). The sensor 54 may be, for example, a programmable system on chip (“PSOC”) residing on the CPU or BMC (PSOC is a registered trademark of Cypress MicroSystems, Inc.). The controller may operate according to a software module 65, such as a system agent or firmware of a CPU or BMC. The electrically insulating substrate 55 prevents the capacitive plates 52 from being electrically bridged by the typically electrically conductive (e.g. metallic) heatsink material. Thus, the capacitive plates 52 are substantially electrically isolated for supporting an electrical charge. The sensor 54 includes a voltage source 56 for electrically energizing the capacitive plates 52 to create an electrical potential (voltage) between the capacitive plates 52 in relation to their capacitance. The fins 42 of the heatsink 40 are spaced apart to define an airflow channel 43 between the fins 42 that is open to the airflow passing through the blade server. The parallel capacitive plates 52 are spaced apart to define an airflow channel 53 that is also open to the airflow passing through the blade server. As dust accumulates in the blade server generally, and on the heatsink fins 42, dust will also accumulate on the pair of capacitive plates 52, causing a change in capacitance between the pair of capacitive plates 52.

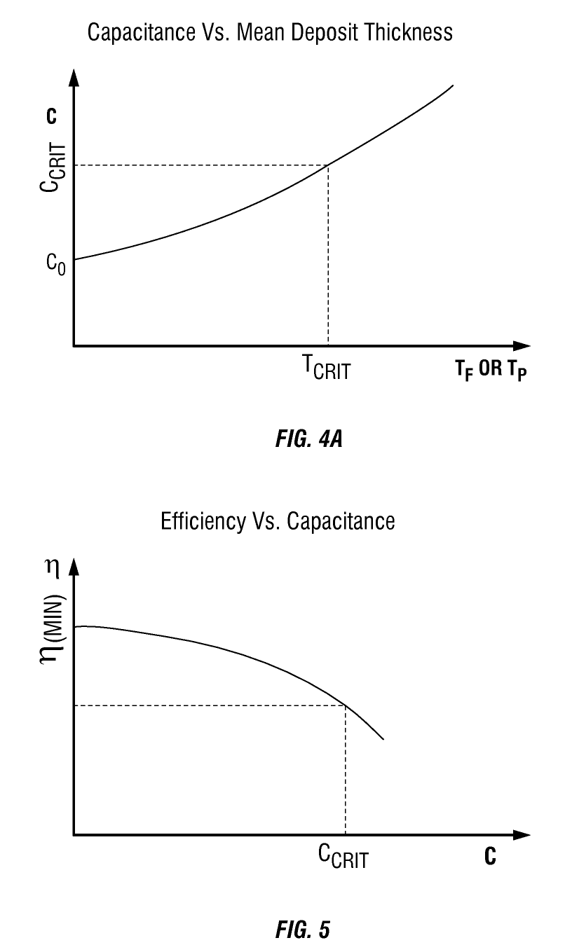

FIG. 4 is a schematic side view of the dust detection system 50 and the heatsink 40 with an accumulation of dust 60 on the fins 42 and the capacitive plates 52. The capacitance “C” between the pair of capacitive plates 52 can be approximated by the relationship C=εA/D, where ε is the effective dielectric constant of the capacitive plates 52, A is the overlapping area of the capacitive plates 52, and D is the distance between the capacitive plates 52. In the absence of any dust, ε is the dielectric constant of air, which is typically about 1.0. The dielectric constant of dust is typically greater than the dielectric constant of air. Thus, the accumulation of dust causes the effective dielectric constant ε and the associated capacitance C of the capacitive plates 52 to increase.

FIG. 4A is a graph illustrating capacitance C as a function of the amount of dust that has accumulated on the capacitive plates 52 in terms of the mean thickness Tp of the dust layer on the capacitive plates 52. The capacitance C has a finite, non-zero value C₀ prior to the accumulation of any dust. As dust accumulates on the capacitive plates 52, the thickness Tp of the dust layer on the capacitive plates 52 increases, with an associated increase in capacitance. As dust accumulates on the capacitive plates 52, dust also accumulates on the heatsink fins 42, because the heatsink fins 42 and the capacitive plates 52 are both open to the airflow. Therefore, an increasing value of the capacitance C also indicates the accumulation of dust on the heatsink fins 42. Thus, the plot of FIG. 4A may also be used to characterize the relationship between the capacitance C and the amount of dust that has accumulated on the heatsink fins 42. The spacing of the capacitive plates 52 is optionally the same as the spacing between heatsink fins 42 so that the accumulation of dust on the plates might be indicative of the accumulation of dust on the fins without requiring empirical correlations.

Dust will continue to accumulate on the heatsink until it reaches a level at which the blade server should be serviced for dust removal. The corresponding thickness of the dust accumulation on the capacitive plates is indicated in the graph as “T_{CRIT},” which may be the mean thickness T_{F} of the dust accumulation on the fins 42 or the mean thickness T_{P} of the dust accumulation on the capacitive plates 52. However, an explicit determination of T_{CRIT} is not required. The corresponding capacitance may be referred to as the “critical capacitance,” which is designated in FIG. 4A as C_{CRIT}.

Referring again to FIG. 4, a capacitance setpoint is selected for the dust detection system 50. The controller 64 may monitor the capacitance between the capacitive plates 52 as an indication of dust accumulation. As may be governed by the software module 65, the controller 64 analyzes the changing value of the sensed capacitance in relation to the setpoint. When the setpoint is reached, an alert may be generated indicating the need to inspect and/or service the hardware device for dust removal. For example, if the selected setpoint is a particular value of capacitance, the controller 64 may compare the sensed capacitance value to the value of the setpoint. The setpoint may be selected as the value of C_{CRIT} (see FIG. 4A) so that the alert is generated when C=C_{CRIT}. The setpoint may instead be selected as a value less than C_{CRIT}, to provide an additional degree of safety by generating the alert prior to reaching the maximum allowable level of dust. The setpoint may alternatively be expressed as a capacitance differential, such as the difference between the critical capacitance C_{CRIT} and the initial capacitance C₀. If the selected setpoint is a capacitance differential, the controller 64 may compute the difference between the initially sensed capacitance and the presently sensed capacitance and compare the computed difference to the setpoint. In any case, the controller 64 may generate an alert in response to reaching the setpoint. For example, if the controller 64 is a BMC, the BMC may generate an alert to a management module that the device in which the dust detection system 50 is installed requires servicing.

A dust detection system may be calibrated according to another inventive aspect. The capacitance between the capacitive plates of a dust detection system may be monitored, along with one or more other hardware parameter such as an efficiency value for the hardware device. The capacitance may be correlated with the hardware parameter (e.g., generating a curve of capacitance versus efficiency). When the hardware parameter reaches an allowable limit (e.g. a minimum acceptable efficiency value), the associated value of the hardware parameter may be noted, along with the value of the capacitance. That capacitance value may be selected as the capacitance setpoint. For example, FIG. 5 is a graph qualitatively describing the decrease in cooling efficiency η of the heatsink 40 (See FIG. 3) as dust accumulates. A minimum acceptable efficiency η(min) may be determined, such as using established criteria in the art for heatsink efficiency. The correlation between efficiency η and capacitance C may be used in the selection of C_{CRIT}. During a calibration phase, the blade server housing a heatsink may be operated beginning with an initially dust-free condition. The values of C and η may be monitored over time. The efficiency η may be obtained using any technique in the art. When the efficiency is determined to have reached the minimum acceptable level η(min), the value of C at that point may be selected as C_{CRIT}.

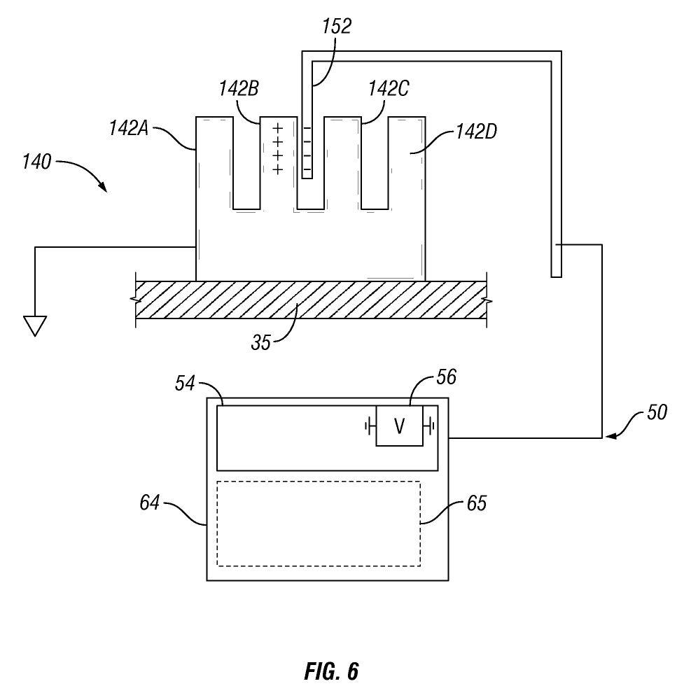

FIG. 6 is a schematic side view of an alternative embodiment of a heatsink 140 coupled with the dust detection system 50. The schematically-drawn heatsink 140 includes four exemplary heatsink fins 142A-D, although any number of fins may be included, and heatsinks with many more than four fins are common. Also, the spacing of heatsink fins is typically closer than in the exaggerated schematic view of FIG. 6. One of the heatsink fins 142B additionally functions as an integral capacitive plate. The other capacitive plate 152 is separate from the heatsink 140 and is electrically isolated from the rest of the heatsink 140 by a gap, as shown. The controller 64, along with the sensor 54, voltage source 56, and software module 65, are configured for detecting dust accumulation at the heatsink 140. The voltage source 56 of the controller 64 electrically energizes the plates 142B, 152, creating a potential difference (voltage) between the plates 142B, 152 in relation to the capacitance between the pair of plates 142B, 152. The isolated plate 152 is much closer to the plate/fin 142B than to the other fins 142A,C,D, so any effect of these other fins on capacitance is assumed negligible for the purpose of this discussion. The plates 142B, 152 define an airflow channel 143 between the plates 142B, 152 that is open to airflow within the hardware device in which the heatsink 140 is installed. As dust accumulates in the blade server generally, and on the heatsink fins 142A-D, dust will also accumulate between the plates 142B, 152, causing a change in capacitance between the pair of plates 142B, 152. This change in capacitance may be monitored according to the invention as an indication of dust accumulation. Desirably, this embodiment makes use of some of the existing design features of a conventional heatsink, by using the heatsink fin 142B as one of the plates 142B of the dust detection system 50.

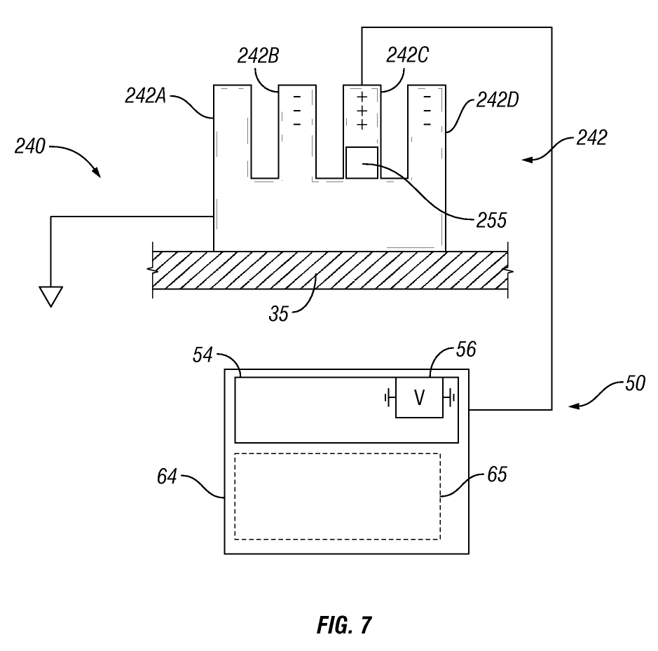

FIG. 7 is a schematic side view of yet another embodiment of a heatsink 240 coupled with the dust detection system 50, wherein a plurality of capacitive plates are integrated with the fins 242A-242D of the heatsink 240. The controller 64, along with the sensor 54, voltage source 56, and software module 65, are configured for detecting dust accumulation at the heatsink 240. One of the fins/plates 242C is electrically coupled to the sensor 54 and is electrically isolated from the rest of the heatsink 240 by an electrically-insulating member 255. The heatsink 240 is electrically grounded, so that the other plates 242A,B,D achieve the opposite polarity of the voltage source 56 and sensor 54. The plate 242A is distant from the electrically isolated plate 242C, and the effect of plate 242A on capacitance is therefore neglected for the purpose of this discussion. The plates 242B and 242D are equidistant from the electrically isolated plate 242C, and may therefore contribute equally to the capacitance between the electrically isolated plate 242C and the plates 242B, 242D. Thus, plates 242B, 242C, and 242D form a multi-plate capacitor whose capacitance varies in relation to the amount of dust that accumulates between them. As dust accumulates in the blade server generally, and on the heatsink fins 242, the change in capacitance may be sensed as an indication of dust accumulation.

The electrically-insulating member 255 may be any of a variety of electrically-insulating materials known in the art. However, many electrically-insulating materials are also thermally-insulating. The use of a thermally-insulating material for the member 255 may, therefore, reduce the effectiveness of the plate 242C as a cooling fine. Thus, if available, an electrically-insulating material that is also reasonably thermally conductive may be used so that the plate 242C provides at least some useful amount of cooling to the heatsink 240. Nonetheless, even if the electrically-insulating member 255 is a poor thermal conductor, the presence of other cooling fins may still provide a desirable amount of cooling. Many heatsinks contain numerous fins, and the loss of cooling from just one fin should have a negligible effect on the cooling capacity of those heatsinks.

The embodiments of FIGS. 3-7 are non-limiting examples of how a dust detection system and method may be implemented, and other embodiments of capacitive dust sensing are within the scope of the invention. A dust detection system as shown and described herein is useful in virtually any electronic system prone to the accumulation of dust. Almost any electronic system may benefit from the ability to automatically, electronically detect the accumulation of dust. Electronic systems having a capacitive dust detection system according to the invention will require much less manual, labor-intensive inspection, with an associated reduction in downtime and maintenance expenses. Electronic systems may be serviced for dust removal and general cleaning on a more logical, as-needed basis, rather than as a matter of routine. For example, system administrators responsible for larger computer systems may spend less time manually inspecting and servicing blade servers and other hardware devices, and may instead respond as needed to alerts individually generated by the blade servers. Thus, system resources are better allocated to those tasks and devices with a demonstrable need for attention.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A system for detecting dust accumulation in an air-cooled hardware device, comprising:
at least two capacitive plates disposed within the hardware device and defining an air channel between the capacitive plates, wherein the air channel is open to the interior of the hardware device;
a sensor in communication with the capacitive plates for sensing a capacitance between the capacitive plates; and
a controller in communication with the sensor for detecting if a capacitance-related setpoint is reached or exceeded.

2. The dust detection system of claim 1, wherein the sensor generates a signal responsive to reaching or exceeding the capacitance setpoint.

3. The dust detection system of claim 2, wherein the setpoint is a selected capacitance differential.

4. The dust detection system of claim 1, further comprising a heatsink disposed in the hardware device, wherein the capacitive plates are positioned in proximity to a heatsink of the hardware device.

5. The dust detection system of claim 4, wherein the capacitive plates are generally aligned with a plurality of fins included with the hardware device.

6. The dust detection system of claim 4, wherein at least one of the capacitive plates is defined by a portion of the heatsink.

7. The dust detection system of claim 4, wherein one or more of the capacitive plates is defined by a fin of the heatsink.

8. The dust detection system of claim 1, wherein the air-cooled hardware device comprises a convection-cooled server.

9. The dust detection system of claim 1, further comprising a management console in communication with the controller for receiving the signal and identifying the hardware device.

10. A method of detecting dust within a hardware device, comprising:
generating airflow through the hardware device;
monitoring the capacitance between capacitive plates disposed within the hardware device, wherein the capacitive plates define an air channel between the capacitive plates open to the interior of the hardware device;
sensing a capacitance between the capacitive plates; and
determining if a capacitance-related setpoint is reached or exceeded.

11. The method of claim 10, further comprising generating a signal responsive to reaching or exceeding the capacitance setpoint.

12. The method of claim 10, wherein the setpoint is a selected capacitance differential.

13. The method of claim 10, wherein at least one of the capacitive plates is defined by a portion of a heatsink disposed within the hardware device.

14. The method of claim 13, wherein at least one of the capacitive plates is defined by one of a plurality of fins of the heatsink.

15. The method of claim 10, further comprising generating a system alert in response to the change in capacitance.

16. The method of claim 10, further comprising:
selecting a threshold value of a hardware parameter;
correlating the capacitance with the hardware parameter; and
selecting a capacitance setpoint as a function of the value of the capacitance corresponding to the threshold value of the hardware parameter.

17. A heat-sink, comprising:
at least two capacitive plates defining an air channel between the capacitive plates; and
a sensor in communication with the capacitive plates for sensing a capacitance between the capacitive plates.

18. The heatsink of claim 17, further comprising:
a plurality of fins, wherein at least one of the fins includes one of the capacitive plates.

19. The heatsink of claim 17, further comprising a controller in communication with the sensor for generating a signal responsive to reaching or exceeding a capacitance-related setpoint.

20. The heatsink of claim 19, wherein the capacitance-related setpoint is a capacitance differential.
